(19) United States
(12) Patent Application Publication
(10) Pub. No.: US 2012/0057395 A1
(43) Pub. Date: Mar. 8, 2012

(54) SEMICONDUCTOR INTEGRATED CIRCUIT

(75) Inventors: Myoung Jin LEE, Icheon-si (KR); Ki Myung KYUNG, Icheon-si (KR)

(73) Assignee: HYNIX SEMICONDUCTOR INC., Icheon-si (KR)

(21) Appl. No.: 12/983,112

(22) Filed: Dec. 31, 2010

(30) Foreign Application Priority Data
Sep. 3, 2010 (KR) 10-2010-0086398

(51) Int. Cl. G11C 11/24

(52) U.S. Cl. 365/149; 365/230.06

(57) ABSTRACT

A semiconductor integrated circuit includes a cell block including a plurality of cell mats having a plurality of word lines and a plurality of bit lines perpendicular to the plurality of word lines, a cell plate electrode formed over a whole area of the cell block, and a plate power mesh line including a first plate power mesh line electrically connected to the cell plate electrode while extending in a direction parallel to the word lines, and a second plate power mesh line extending in a direction parallel to the bit lines. The first plate power mesh line includes at least one cutting part.

The present application claims priority under 35 U.S.C. §119(a) to Korean application number 10-2010-0086398, filed on Sep. 3, 2010, in the Korean Intellectual Property Office, which is incorporated herein by reference in its entirety.

### BACKGROUND

1. Technical Field

The present invention relates generally to a semiconductor integrated circuit, and more particularly to a semiconductor memory apparatus having a power mesh structure.

2. Related Art

The operating voltages needed to access data in a semiconductor memory apparatus may include external power supply voltage, ground voltage, internal power supply voltage, reference voltage, and high voltage. The operating voltages are transferred to the cell regions of a semiconductor memory apparatus through power lines.

With high integration density and storage capacity continuing to increase, the number of signal lines needed in a semiconductor memory also increases. The signal lines are arranged mostly in a cell array region. The power lines for transferring power are arranged to extend horizontally and vertically in the peripheral circuit regions on the peripheries of the cell array region. The power lines are arranged in a meshed structure, in which the power lines having the same level are coupled to each other through via contacts.

On the other hand, in a semiconductor memory apparatus, a cell plate electrode in a capacitor is formed over the area of a memory cell block (for example, a bank) having a plurality of mats. Plate power mesh lines that are coupled to cell plate electrode are arranged to extend in the word line direction and the bit line direction on the bottom or top surface of the cell plate electrode.

Accordingly, the plate power mesh lines are arranged to extend across the mats constituting a memory cell block.

However, because the plate power mesh lines are extended throughout the entire memory cell block, the plate power mesh lines are vulnerable against noise.

Specifically, when activating a specific word line, a plate voltage may be susceptible to change due to coupling with a bit line holding a signal level for data.

Furthermore, such plate voltage variations could be transferred along the plate power mesh lines arranged parallel to word lines extending to an adjacent mat and could influence the plate electrode in the adjacent mat.

### SUMMARY

In an embodiment of the present invention, a semiconductor integrated circuit includes: a cell block including a plurality of cell mats having a plurality of word lines and a plurality of bit lines perpendicular to the plurality of word lines; a cell plate electrode disposed over an area of the cell block; and a plate power mesh line including a first plate power mesh line electrically connected to the cell plate electrode while extending in a direction parallel to the word lines, and a second plate power mesh line extending in a direction parallel to the bit lines, wherein the first plate power mesh line includes at least one cutting part.

In another embodiment of the present invention, a semiconductor integrated circuit includes a cell block including a plurality of cell mats having a plurality of word lines and a plurality of bit lines perpendicular to the plurality of word lines; a cell plate electrode disposed over an area of the cell block; and a plate power mesh line electrically connected to the cell plate electrode and extending in a direction parallel to the bit lines.

### BRIEF DESCRIPTION OF THE DRAWINGS

Features, aspects, and embodiments are described in conjunction with the attached drawings, in which:

FIG. 1 is a schematic plan view of a semiconductor memory apparatus according to an embodiment of the invention;

FIG. 2 is a perspective view schematically illustrating a part of a cell mat according to an embodiment of the invention;

FIG. 3 is a perspective view illustrating the electrical connection relationship between a plate electrode and plate power mesh lines according to an embodiment of the invention; and

FIGS. 4 and 5 are schematic plan view of a semiconductor memory apparatus according to another embodiment of the invention.

### DETAILED DESCRIPTION

Hereinafter, a semiconductor integrated circuit according to exemplary embodiments of the present invention will be described below with reference to the accompanying drawings.

FIG. 1 is a schematic plan view of a semiconductor memory apparatus according to an embodiment of the invention.

Referring to FIG. 1, the semiconductor memory apparatus includes a plurality of cell blocks 100. The cell block 100 may be called a bank. Each cell block 100 includes a plurality of cell mats 110 (or may also be called a unit cell array). Each cell mat 110 may include a plurality of unit memory cells having a plurality of word lines (not shown) and a plurality of bit lines (not shown) crossing each other.

In the cell block 100, sub-word line driver areas 120 are positioned on respective sides of the cell mats 110, which are perpendicular to the word line extension direction WL, and sense amp array areas 130 are positioned on respective sides of the cell mats 110, which are perpendicular to the bit lines. Reference numeral 140 denotes a cross area.

The cell mat includes the plurality of unit memory cells as described above. Each memory cell may include switching transistors (not shown) and capacitors (not shown). A switching transistor of a memory cell is connected between a word line and a bit line, and a capacitor is provided in a space surrounded by the word lines and the bit lines, so that the unit memory cell according to an embodiment of the present invention may have an area of 4F². Nevertheless, the present invention is not limited thereto, and the present invention may be applied to, for example, 6F² and 8F². The ‘F’ denotes a minimum feature size.

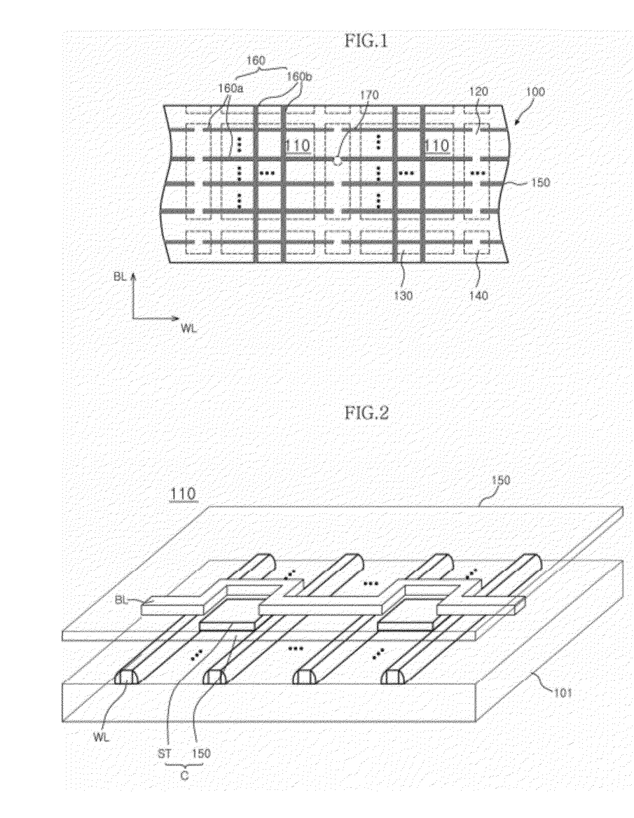

FIG. 2 is a perspective view illustrating a part of the cell mat according to the embodiment of the invention.

Referring to FIG. 2, a capacitor C includes a storage electrode ST, a plate electrode 150, and a dielectric (not shown).

One storage electrode ST may be formed every unit cell memory, and the plate electrode 150 may be formed to cover one bank, that is, the entire cell block 100. That is, the plate electrode 150 may be formed to simultaneously cover the plurality of the cell mats 110 including the plurality of the unit memory cells. The dielectric includes an insulation layer interposed between the storage electrodes ST and the plate electrode 150.

The storage electrode ST is configured to receive an electrical signal through a storage node contact section (not shown) electrically connected to an active region of one side of the word line WL, that is, a source region (not shown).

The bit line BL, being substantially perpendicular to the word line WL, is configured to be electrically connected to an active region of the other side of the word line WL, that is, a drain region (not shown)

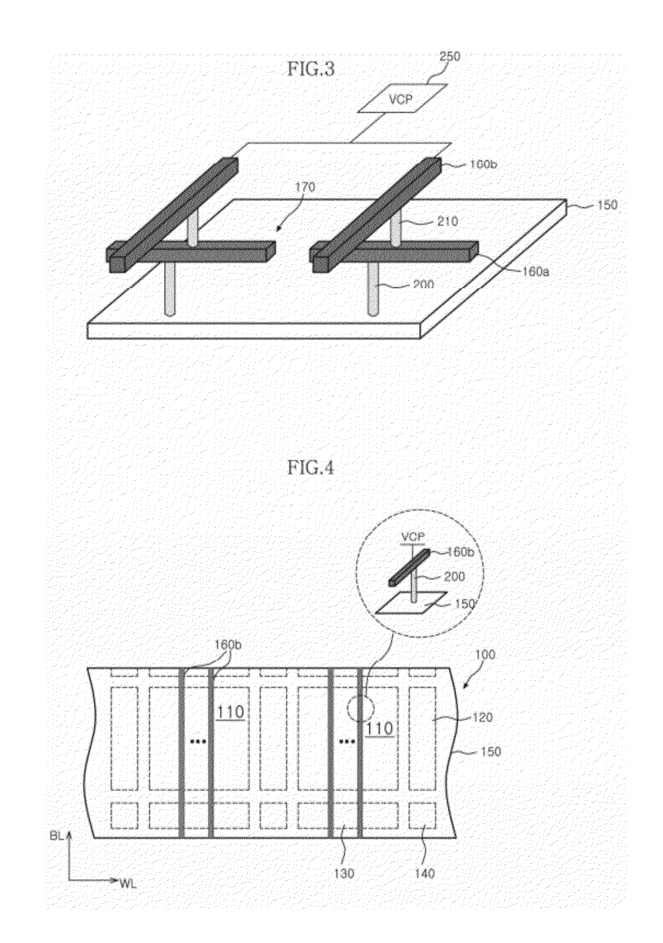

The plate electrode 150 is configured to be electrically connected to a plate power mesh line 160 (see FIG. 1) for transferring a plate voltage Vcp as illustrated in FIGS. 1 and 3 per the cell pats. The plate power mesh line 160 may include a first plate power mesh line 160a extending in the word line extension direction WL and a second plate power mesh line 160b extending in the bit line extension direction BL such that the plate voltage Vcp is uniformly transferred to all parts of the plate electrode 150. Each of the first and second plate power mesh lines 160a, 160b may be provided in plurality.

Referring to FIGS. 1 and 3, the first plate power mesh line 160a has at least one cutting part 170 in order to substantially prevent noise occurring by coupling with a corresponding bit line when a specific word line is activated from being transferred to an adjacent cell mat. In an embodiment of the present invention, the cutting part 170 may be positioned in the sub-word line driver area 120, that is, an area between the cell mats 110.

For example, as shown in FIG. 3, the first plate power mesh line 160a may be formed above the plate electrode 150 and connected to the plate electrode 150 through a first contact part 200. The second plate power mesh line 160b may be formed above the first plate power mesh line 160a while crossing the first plate power mesh line 160a, and the second plate power mesh line 160b and the first plate power mesh line 160a may be electrically connected to each other through a second contact part 210. Although not shown in FIG. 3, the structure of FIG. 2 may be formed below the plate electrode 150 of FIG. 3.

Although not shown in FIG. 3, an insulation layer is formed in between the plate electrode 150 and the first plate power mesh line 160a and between the first plate power mesh line 160a and the second plate power mesh line 160b. In an embodiment of the present invention, the first plate power mesh line 160a parallel to a word line WL is formed below the second plate power mesh line 160b, and the second plate power mesh line 160b parallel to a bit line BL is formed above the first plate power mesh line 160a. However, the first plate power mesh line 160a may be formed above the second plate power mesh line 160b to achieve the same result

Although the first plate power mesh line 160a has at least one cutting part 170, the plate voltage Vcp can be easily transferred throughout the plate electrode 150 since the first plate power mesh line 160a is electrically connected to the second plate power mesh line 160b formed above or below the first plate power mesh line 160a through the contact part 210.

A plate voltage generation unit 250 is electrically connected to the second plate power mesh line 160b formed relatively above the plate voltage generation unit 250, thereby providing the plate voltage Vcp to the plate electrode 150.

As described above, noise is not transferred to a cell mat from an adjacent cell mat since the first plate power mesh line 160a extending in parallel to the word line is partially cut, and thus the noise from an adjacent mat is substantially prevented from being introduced.

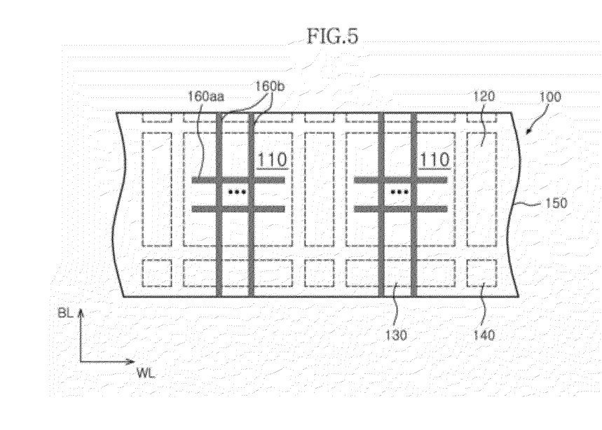

It should noted that it is possible to omit a first plate power mesh line 160a in an embodiment of the present invention as shown in FIG. 4. In other words, the plate power mesh line may extend only in the direction parallel to the bit line BL according to an embodiment of the present invention. Thus, the second plate power mesh line 160b parallel to the bit line would make a direct contact with a plate voltage source and the plate electrode 150. In such a case, the noise transfer between cell mats is fundamentally blocked since the first plate power mesh line 160a extending in parallel to the word line direction WL does not exist.

As shown in FIG. 5, a first plate power mesh line 160aa parallel to the word line may be positioned above only the cell mat. Even in such a case, since the path extending to an adjacent cell mat is blocked, the possibility of noise being transferred is blocked.

As described in detail above, according to an embodiment of the invention, the plate voltage line, which is parallel to the word line and causes the transfer of noise, has at least one cutting part. Consequently, transfer of noise to an adjacent cell mat is blocked, by which a plate voltage can be stably supplied and thus data retention time is ensured.

While certain embodiments have been described above, it will be understood to those skilled in the art that the embodiments described are by way of example only. Accordingly, the semiconductor integrated circuit described herein should not be limited based on the described embodiments. Rather, the semiconductor integrated circuit described herein should only be limited in light of the claims that follow when taken in conjunction with the above description and accompanying drawings.

What is claimed is:

1. A semiconductor integrated circuit comprising:
a cell block comprising a plurality of cell mats, each including a word line and a bit line arranged to cross each other;
a cell plate electrode disposed over an area of the cell block; and
a plate power mesh line comprising a first plate power mesh line electrically connected to the cell plate electrode while extending in a direction parallel to the word line, and a second plate power mesh line extending in a direction parallel to the bit line,
wherein the first plate power mesh line includes at least one cutting part.

2. The semiconductor integrated circuit according to claim 1, wherein the first plate power mesh line is positioned above only the cell mat.

3. The semiconductor integrated circuit according to claim 1, further comprising a sub-word line driver area provided in a space between the cell mats perpendicular to the word line.

4. The semiconductor integrated circuit according to claim 3, wherein the cutting part is positioned in the sub-word line driver area.

5. The semiconductor integrated circuit according to claim 1, wherein the first plate power mesh line cut by the cutting part is electrically connected to the cell plate electrode.

6. A semiconductor integrated circuit comprising:
a cell block comprising a plurality of cell mats, each having a word line and a bit line arranged to cross each other;
a cell plate electrode formed over an area of the cell block; and
a plate power mesh line electrically connected to the cell plate electrode and extending in a direction parallel to the bit lines,
wherein the plate power mesh line extending in the direction parallel to the bit lines makes a contact with the cell plate electrode.

7. The semiconductor integrated circuit according to claim 6, further comprising an additional plate power mesh line which extends in a direction parallel to the word line, has at least one cutting part, and is electrically connected to the plate power mesh line.

8. The semiconductor integrated circuit according to claim 7, wherein the cutting parts is formed in a space between the cell mats perpendicular to the word lines.

9. The semiconductor integrated circuit according to claim 6, wherein the plate power mesh line is electrically connected to a plate voltage source.

10. A semiconductor integrated circuit comprising:
first and second cell mats positioned in a bank including a word line and a bit line;
a plurality of storage node electrodes positioned in the first cell mat and the second cell mat, respectively;
a cell plate electrode formed to cover the first cell mat and the second cell mat, respectively; and
a plate power mesh line formed above the cell plate electrode while being electrically connected to the cell plate electrode and extending in a direction parallel to the word line,
wherein the plate power mesh line is cut between the first cell mat and the second cell mat.

11. The semiconductor integrated circuit according to claim 10, further comprising an additional plate power mesh line electrically connected to the plate power mesh line and extending in parallel to the bit line.

12. The semiconductor integrated circuit according to claim 11, wherein the plate power mesh line makes direct contact with the cell plate electrode and the additional plate power mesh line is electrically connected to a plate voltage source.

13. The semiconductor integrated circuit according to claim 11, wherein the plate power mesh line is positioned only in the first cell mat or the second cell mat.
